(19) United States
(12) Patent Application Publication
(10) Pub. No.: US 2024/0284683 A1
(43) Pub. Date: Aug. 22, 2024

(54) NONVOLATILE MEMORY PACKAGE, STORAGE DEVICE HAVING THE SAME, AND METHOD OF MANUFACTURING THE SAME

(71) Applicant: Samsung Electronics Co., Ltd., Suwon-si (KR)

(72) Inventors: Jungmin Seo, Suwon-si (KR); Manho Lee, Suwon-si (KR); Sukkang Sung, Suwon-si (KR); Cheonan Lee, Suwon-si (KR)

(21) Appl. No.: 18/244,429

(22) Filed: Sep. 11, 2023

(30) Foreign Application Priority Data
Feb. 22, 2023 (KR) 10-2023-0023498

(51) Int. Cl. H10B 80/00; H01L 25/00; H01L 25/065; H01L 25/18

(52) U.S. Cl. CPC H10B 80/00; H01L 25/0652; H01L 25/18; H01L 25/50; H01L 2225/06506; H01L 2225/06537; H01L 2225/06562; H01L 2225/06582

(57) ABSTRACT

A nonvolatile memory package includes first nonvolatile memory devices configured to be stacked, second nonvolatile memory devices configured to be stacked, and an interface chip connected to an external device through a bonding channel, connected to one of the first nonvolatile memory devices through a first bonding channel, and connected to one of the second nonvolatile memory devices through a second bonding channel, wherein the interface chip includes input/output pads connected to the bonding channel, first input/output pads connected to the first bonding channel, and second input/output pads connected to the second bonding channel, and wherein, for cross-channel shielding, the first input/output pads and the second input/output pads are alternately arranged for each channel.

### CROSS-REFERENCE TO RELATED APPLICATIONS

This application claims benefit of priority to Korean Patent Application No. 10-2023-0023498 filed on Feb. 22, 2023 in the Korean Intellectual Property Office, the disclosure of which is incorporated herein by reference in its entirety.

### BACKGROUND

Example embodiments of the present disclosure relate to a nonvolatile memory package, a storage device having the same, and a method of manufacturing the same.

Generally, a memory package may include a plurality of memory chips mounted on a package substrate. The storage device may include at least one memory package. The storage device may include a controller for controlling the memory package. The controller may control a plurality of memory chips through a buffer chip included in a memory package. As a data storage space required by various electronic devices increases, the demand for a memory package in which buffer chips and memory chips are efficiently disposed and a storage device has been gradually increased.

### SUMMARY

An example embodiment of the present disclosure is to provide a nonvolatile memory package which may have a chip having a reduced size, a storage device having the same, and a method of manufacturing the same.

An example embodiment of the present disclosure is to provide a nonvolatile memory package which may increase the degree of freedom of package development, a storage device having the same, and a method of manufacturing the same.

According to an example embodiment of the present disclosure, a nonvolatile memory package includes first nonvolatile memory devices configured to be stacked; second nonvolatile memory devices configured to be stacked; and an interface chip connected to an external device through a bonding channel, connected to one of the first nonvolatile memory devices through a first bonding channel, and connected to one of the second nonvolatile memory devices through a second bonding channel, wherein the interface chip includes input/output pads connected to the bonding channel; first input/output pads connected to the first bonding channel; and second input/output pads connected to the second bonding channel, and wherein, for cross-channel shielding, the first input/output pads and the second input/output pads are alternately arranged for each channel.

According to an example embodiment of the present disclosure, a storage device includes a nonvolatile memory package; and a controller connected to the nonvolatile memory package through a channel and configured to control the nonvolatile memory package, wherein the nonvolatile memory package includes first nonvolatile memory devices connected to a first internal channel; second nonvolatile memory devices connected to a second internal channel; an interface chip connected to the first internal channel and the second internal channel, wherein the interface chip includes input/output pads disposed in a first row and connected to the channel; first input/output pads connected to the first internal channel; and second input/output pads connected to the second internal channel, and wherein the first input/output pads and the second input/output pads are alternately arranged for each channel.

According to an example embodiment of the present disclosure, a method of manufacturing a nonvolatile memory package includes manufacturing a buffer chip on a first sub-silicon substrate; manufacturing nonvolatile memory chips stacked on a second sub-silicon substrate; and connecting the buffer chip to the nonvolatile memory chips using cross-channel shielding, wherein the buffer chip includes input/output pads connected to a bonding channel; first input/output pads connected to a first bonding channel; and second input/output pads connected to a second bonding channel, and wherein the first input/output pads and the second input/output pads are alternately arranged for each channel.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a diagram illustrating a storage device according to an example embodiment of the present disclosure;

FIG. 2 is a diagram illustrating a nonvolatile memory device according to an example embodiment of the present disclosure;

FIG. 3A is a diagram illustrating a nonvolatile memory package implemented in a stacked form according to an example embodiment of the present disclosure;

FIG. 3B is a diagram illustrating rows of pads of an interface chip according to an example embodiment of the present disclosure;

FIG. 4A is a diagram illustrating wiring of a nonvolatile memory package according to an example embodiment of the present disclosure;

FIG. 4B is a plan diagram illustrating the illustrating the wiring of the nonvolatile memory package in FIG. 4A according to an example embodiment of the present disclosure;

FIG. 5 is a diagram illustrating a nonvolatile memory package according to another example embodiment of the present disclosure;

FIG. 6 is a diagram illustrating a nonvolatile memory package according to another example embodiment of the present disclosure;

FIG. 7 is a diagram illustrating a nonvolatile memory package according to another example embodiment of the present disclosure;

FIG. 8 is a flowchart illustrating a method of manufacturing a nonvolatile memory package according to an example embodiment of the present disclosure;

FIG. 9 is a diagram illustrating a storage device according to another example embodiment of the present disclosure;

FIG. 10 is a diagram illustrating a storage device according to an example embodiment of the present disclosure;

FIG. 11 is a diagram illustrating a nonvolatile memory device according to an example embodiment of the present disclosure; and

FIG. 12 is a diagram illustrating a data center to which a memory device according to an example embodiment is applied.

### DETAILED DESCRIPTION

Hereinafter, embodiments of the present disclosure will be described as below with reference to the accompanying drawings.

A nonvolatile memory package, a storage device including the same, and a method of manufacturing the same according to an example embodiment may be implemented with an input/output buffer structure using cross-channel shielding and memory channel bonding. Accordingly, the nonvolatile memory package, the storage device, and the method of manufacturing the same may enable input/output pads to be disposed in 1-row, thereby overcoming design limitations and allowing bonding wire environment between channels to be uniform.

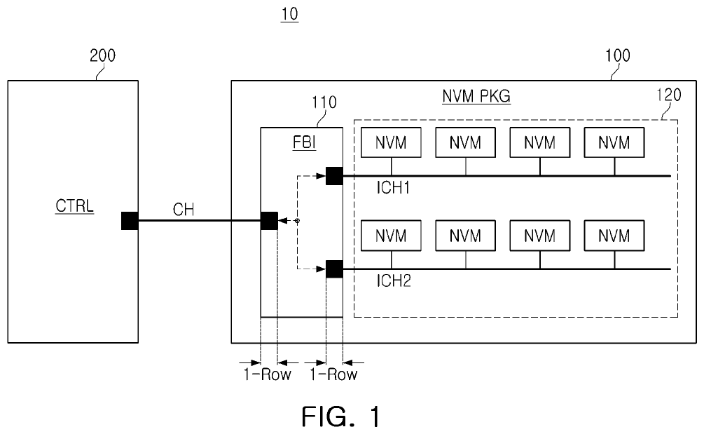

FIG. 1 is a diagram illustrating a storage device 10 according to an example embodiment. Referring to FIG. 1, the storage device 10 may include a nonvolatile memory package 100 NVM PKG and a controller 200 CTRL controlling the nonvolatile memory package 100.

The nonvolatile memory package 100 NVM PKG may include an interface chip 110 (e.g., a frequency boosting interface chip (F-chip) or “buffer chip”) and a plurality of nonvolatile memory devices 120 NVMs connected to internal channels ICH1 and ICH2. Meanwhile, the number of internal channels ICH1 and ICH2 illustrated in FIG. 1 may be two, but the number of internal channels in the example embodiment may not be limited thereto.

The interface chip 110 FBI may be connected to the controller 200 through a channel CH. Channel CH may also be referred to herein as an external channel or simply a bonding channel. Here, the channel CH may be connected to the first internal channel ICH1 and/or the second internal channel ICH2 through the interface chip 110. The first internal channel ICH1 and the second internal channel ICH2 may also be referred to herein as a first bonding channel and a second bonding channel respectively. The interface chip 110 may include a retraining check circuit which internally determines the need for retraining (i.e., the need to realign a data signal transmitted on a channel and a clock signal). The retraining check circuit may be implemented to determine the need for retraining using a non-selected channel among internal channels ICH1 and ICH2. In an example embodiment, the retraining check circuit may include a built-in self-test BIST circuit, an oscillator, or a delayed locked loop (DLL) circuit.

The interface chip 110 may include a plurality of input/output pads PADs connected to the channel CH. The plurality of input/output pads PADs connected to the channel CH may also be referred to herein as external channel input/output pads PADs or bonding channel input/out pads PADs. The interface chip 110 may include first input/output pads PAD1 connected between a plurality of input/output pads PADs and a first internal channel ICH1.

The interface chip 110 may also include second input/output pads PAD2 connected between a plurality of input/output pads PADs and a second internal channel ICH2. In an example embodiment, the input/output pads PADs may be disposed in a row 1-Row on the controller 200 side. Also, the first input/output pads PAD1 and the second input/output pads PAD2 may be disposed in a row 1-Row on the nonvolatile memory side. Although the term “row” has been used herein to describe the arrangement of the input/output pads PADs, the first input/output pads PAD1, and the second input/output pads PAD2 on the interface chip 110, it is understood that the term “column” may alternatively be used depending on an orientation of the interface chip 110.

In an example embodiment, for cross-channel shielding, the first input/output pads PAD1 and the second input/output pads PAD2 may be alternately arranged for each channel. For example, the first input/output pads PAD1 and the second input/output pads PAD2 may be alternately arranged in 1-row or may be alternately arranged in a zigzag pattern. For example, one of the second input/output pads PAD2 may be disposed in neighboring of one of the first input/output pads PAD1.

Each of the nonvolatile memory devices 120 NVM may be implemented to store data. A plurality of nonvolatile memory devices may be connected to each of the internal channels ICH1 and ICH2. In FIG. 1, four nonvolatile memory devices may be connected to each of the internal channels ICH1 and ICH2, but the number of nonvolatile memory devices connected to the internal channels ICH1 and ICH2 in the example embodiment is not limited thereto. In an example embodiment, the nonvolatile memory package 100 may be implemented as a structure in which the nonvolatile memory devices 120 (memory chips) are stacked.

The controller 200 CTRL may be implemented to control overall operations of the nonvolatile memory package 100. The controller 200 may perform functions required for data management of the nonvolatile memory package 100, such as address mapping, error correction, garbage collection, wear-leveling, bad block management, or data correction. Here, these functions may be implemented in terms of hardware, software, or firmware.

The controller 200 may receive a retraining request from the nonvolatile memory package 100, may issue a retraining command, and may transmit the retraining command to the nonvolatile memory package 100. Accordingly, the nonvolatile memory package 100 may perform a retraining operation corresponding to a non-selected channel.

A general storage device may include rows of pads corresponding to each internal channel and a nonvolatile memory package for arranging shielding pads to ensure data reliability of the internal pads, which may increase a size of a chip of the nonvolatile memory package and may limit the freedom of development.

The storage device according to the example embodiment may include an interface chip 110 for alternately disposing pads for each internal channel for cross-channel shielding and disposing internal rows of pads in a row, thereby increasing the degree of freedom of package development and omitting the arrangement of a shielding pad.

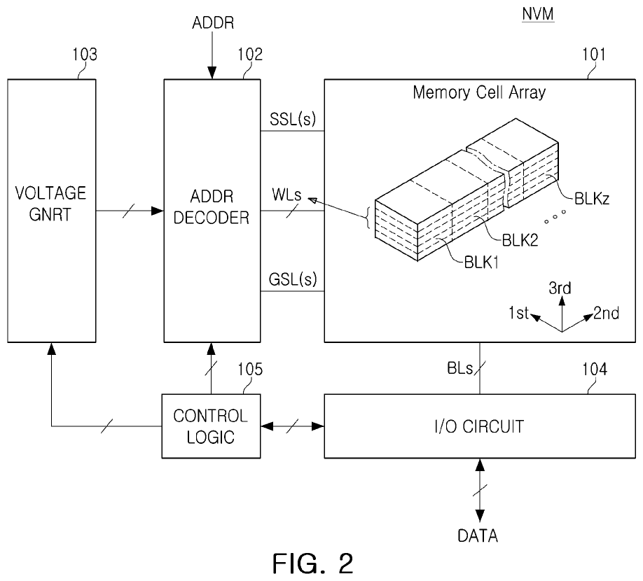

FIG. 2 is a diagram illustrating a nonvolatile memory device NVM according to an example embodiment. Referring to FIG. 2, the nonvolatile memory device NVM may include a memory cell array 101, an address decoder 102, a voltage generator circuit 103, an input/output circuit 104 and a control logic 105.

The nonvolatile memory device NVM may be implemented as a NAND flash memory, vertical NAND flash memory (vertical NAND; VNAND), NOR flash memory, resistive random access memory (RRAM), phase-change memory (PRAM), magnetoresistive random access memory (MRAM), ferroelectric random access memory (FRAM), or spin transfer torque random access memory (STT-RAM). In the description below, a nonvolatile memory device NVM will be referred to as a vertical NAND flash memory device for ease of description.

The memory cell array 101 may include a plurality of memory blocks BLK1-BLKz. Each of the memory blocks BLK1-BLKz may be connected to the address decoder 102 through wordlines WLs, at least one string selection line SSL and at least one ground selection line GSL, and may be connected to the input/output circuit 124 via bitlines BLs. In an example embodiment, wordlines WLs may be provided in a stacked plate structure.

Each of the plurality of memory blocks BLK1-BLKz may include a plurality of strings of a three-dimensional structure arranged in first and second directions (different from the first direction) on the board and arranged in a third direction (direction perpendicular to the plane formed by the first and second directions). Here, each of the plurality of strings may include at least one string select transistor, a plurality of memory cells, and at least one ground select transistor connected to each other in series between a bitline and a common source line CSL. Here, each of the plurality of memory cells may be implemented to store at least one bit in which the wordlines WLs and the bitlines BLs intersect each other. In an example embodiment, at least one dummy cell may be included between at least one string select transistor and a plurality of memory cells. In another example embodiment, at least one dummy cell may be included between a plurality of memory cells and at least one ground select transistor.

The address decoder 102 may be implemented to select one of a plurality of memory blocks BLK1-BLKz in response to an address. Also, the address decoder 102 may be connected to the memory cell array 101 through wordlines WLs, at least one string selection line SSL and at least one ground selection line GSL. The address decoder 102 may select wordlines WLs, a string selection line SSL, and a ground selection line GSL using the decoded row address. Also, the address decoder 102 may decode a column address among input addresses. Here, the decoded column address may be transmitted to the input/output circuit 104. In an example embodiment, the address decoder 102 may include a row decoder, a column decoder, and an address buffer.

The voltage generator circuit 103 may be implemented to generate voltages (program voltage, pass voltage, read voltage, read pass voltage, verify voltage, erase voltage, common source line voltage, well voltage, or the like) required for operation. The voltage generator circuit 103 may generate a wordline voltage required for program/read/erase operations.

The input/output circuit 104 may be connected to the memory cell array 101 through bitlines BLs. The input/output circuit 104 may be implemented to receive the decoded column address from the address decoder 102. The input/output circuit 104 may select bitlines BLs using the decoded column address. The input/output circuit 104 may include a plurality of page buffers to store data to be programmed during a program operation or to store read data during a read operation. Here, each of the plurality of page buffers may include a plurality of latches. During a program operation, data stored in page buffers may be programmed into pages corresponding to selected memory blocks through bitlines BLs. During a read operation, read data from the page corresponding to the selected memory block may be stored in page buffers through the bitlines BLs. Meanwhile, the input/output circuit 104 may read data from the first region of the memory cell array 101 and may store the read data in the second region of the memory cell array 101. For example, the input/output circuit 104 may be implemented to perform copy-back.

The control logic 105 may be implemented to control overall operations (program/read/erase operations) of the nonvolatile memory device NVM. The control logic 105 may operate in response to control signals or commands input from an external entity.

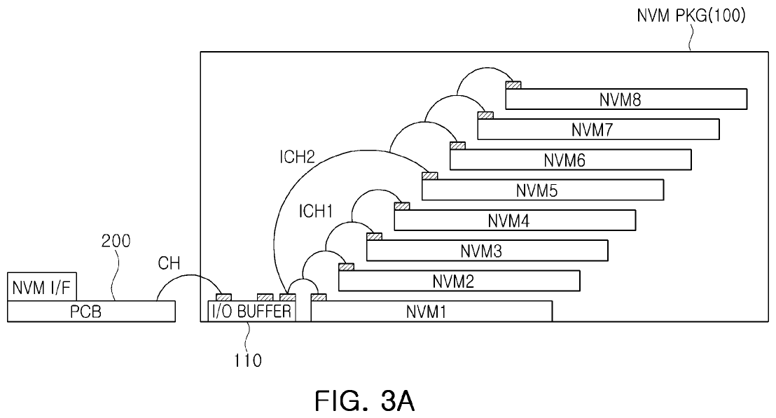

FIG. 3A is a diagram illustrating a nonvolatile memory package 100 implemented in a stacked form according to an example embodiment. FIG. 3B is a diagram illustrating rows of pads of an interface chip 110 according to an example embodiment.

Referring to FIG. 3A, the nonvolatile memory package 100 NVM PKG may include an interface chip 110 (also referred to as “buffer chip”), first nonvolatile memory devices NVM1-NVM4 (also referred to as first nonvolatile memory chips), and second nonvolatile memory devices NVM5-NVM8 (also referred to as second nonvolatile memory chips).

The interface chip 110 (buffer chip) may be connected to a board PCB of the controller 200 through a channel CH. The channel CH may be connected to pads PAD of the interface chip 110. In an example embodiment, interface chip 110 may be formed on a first sub-silicon substrate.

The first nonvolatile memory devices NVM1-NVM4 may be connected to the interface chip 110 through a first internal channel ICH1. Here, the first nonvolatile memory devices NVM1-NVM4 may be stacked on each other. The first internal channel ICH1 may be connected to first input/output pads PAD1 of the interface chip 110. The second nonvolatile memory devices NVM5-NVM8 may be connected to the interface chip 110 through a second internal channel ICH2. Here, the second nonvolatile memory devices NVM5-NVM8 may be stacked on each other. The second internal channel ICH2 may be connected to the second input/output pads PAD2 of the interface chip 110. In an example embodiment, the nonvolatile memory devices NVM1-NVM8 may be formed on the second sub-silicon substrate. Although not illustrated, a first sub-silicon substrate and a second sub-silicon substrate may be disposed on the package board of the nonvolatile memory package 100.

The number of stacked nonvolatile memory devices illustrated in FIG. 3A may be eight, but an example embodiment thereof is not limited thereto.

Referring to FIG. 3B, the interface chip 110 may be disposed in 2-rows of pads. The first row of pads may include data pads DQ1-DQ4 of pads PAD. The second row of pads may include the data pads DQ1-DQ4 of first input/output pads PAD1 and the data pads DQ1-DQ4 of second input/output pads PAD2. The data pads DQ1-DQ4 of the first input/output pads PAD1 and the data pads DQ1-DQ4 of the second input/output pads PAD2 may be alternately arranged in the second row of pads for each channel to provide for cross-channel shielding.

In an example embodiment, during a read operation or a write operation, the input/output pads PAD may be electrically connected to one of first input/output pads PAD1 and the second input/output pads PAD2. Generally, the entirety of channels may not be activated simultaneously, such that when data is transmitted to a pad of one channel, data may not be transmitted to the pad of an adjacent channel. Accordingly, the interface chip 110 may obtain a shielding effect when transmitting data without a shielding pad.

The number of data pads illustrated in FIG. 3B may be four, but the number of data pads in the example embodiment is not limited thereto.

Also, a data pad corresponding to a channel is illustrated in FIG. 3B, but the example embodiment may be equally applied to a pad transmitting other signals included in the channel in addition to the data pad.

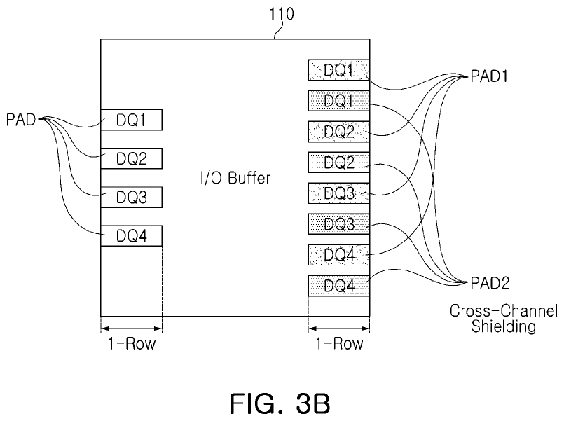

FIG. 4A is a diagram illustrating wiring of a nonvolatile memory package 100 according to an example embodiment. FIG. 4B is a plan diagram illustrating a nonvolatile memory package 100 according to an example embodiment.

In FIG. 4A, it is assumed that two nonvolatile memory stacks may be connected to a channel for ease of description. Referring to FIG. 4A, pads (e.g., PAD in FIG. 1) of the interface chip 110 may be connected to bonding pads of the controller 200 through channel bonding.

In an example embodiment, signal pads of first input/output pads (e.g., PAD1 in FIG. 1) of interface chip 110 may be connected to signal pads S of the nonvolatile memory stack 121-2 (also referred to as nonvolatile memory chip) through first channel bonding 141. Here, a ground pad G and a power pad P of the nonvolatile memory stack 121-2 may be alternately disposed between pairs of the signal pads S. For example, one of the ground pad G and the power pad P is alternately arranged between the signal pads S.

In an example embodiment, the ground pad G and the power pad P of the nonvolatile memory stack 121-2 may be connected to the ground pad G and the power pad P of the nonvolatile memory stack 121-1 as illustrated in FIG. 4A. In an example embodiment, the ground pad G and the power pad P of the nonvolatile memory stack 121-1 may be connected to corresponding pads of the bonding region 130, as illustrated in FIG. 4A.

The signal pads of the second input/output pads (e.g., PAD2 in FIG. 1) of the interface chip 110 may be connected to signal pads S of the nonvolatile memory stack 122-1 through second channel bonding 142. Here, a ground pad G and a power pad P of the nonvolatile memory stack 122-1 may be alternately disposed between pairs of the signal pads S. For example, one of the ground pad G and the power pad P is alternately arranged between the signal pads S.

In an example embodiment, the ground pad G and the power pad P of the nonvolatile memory stack 122-1 may be connected to the ground pad G and the power pad P of the nonvolatile memory stack 122-2 as illustrated in FIG. 4A. In an example embodiment, the ground pad G and the power pad P of the nonvolatile memory stack 122-1 may be connected to the ground pad G and the power pad P of the nonvolatile memory stack 121-2 as illustrated in FIG. 4A.

Referring to FIG. 4B, the nonvolatile memory package 100 may include an interface chip 110, nonvolatile memory stacks 121-1, 121-2, 122-1, and 122-2, and a bonding region 130. The interface chip 110 may include a channel pad array 111 having a structure in which signal pads of two independent channels are alternately arranged.

The first nonvolatile memory stacks 121-1 and 121-2 may be connected to the first input/output pads (PAD1, see FIG. 1) of the interface chip 110 corresponding to the first internal channel (ICH1, see FIG. 1) by first channel bonding 141. The second nonvolatile memory stacks 122-1 and 122-2 may be connected to second input/output pads (PAD2, see FIG. 1) of the interface chip 110 corresponding to the second internal channel (ICH2, see FIG. 1) by the second channel bonding 142.

In an example embodiment, the first nonvolatile memory stacks 121-1 and 121-2 and the second nonvolatile memory stacks 122-1 and 122-2 may be alternately arranged horizontally with a predetermined distance therebetween.

Wiring between a nonvolatile memory package and an interface chip according to example embodiment may be implemented in various manners.

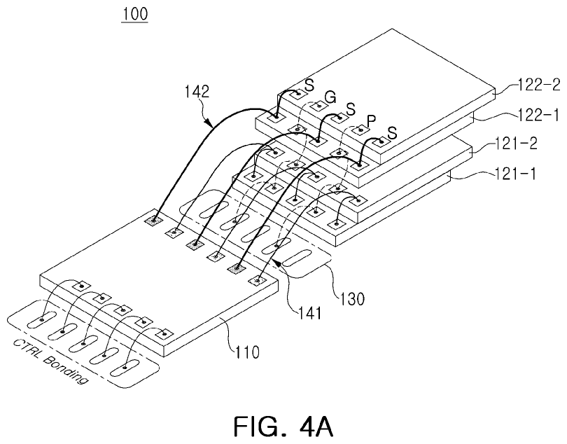

FIG. 5 is a diagram illustrating a nonvolatile memory package according to another example embodiment. Referring to FIG. 5, the nonvolatile memory package 100a may be connected to signal pads S of the nonvolatile memory stack 121-1, instead of the nonvolatile memory stack 121-2, through the first channel bonding 141a as compared to the nonvolatile memory package 100 illustrated in FIG. 4A.

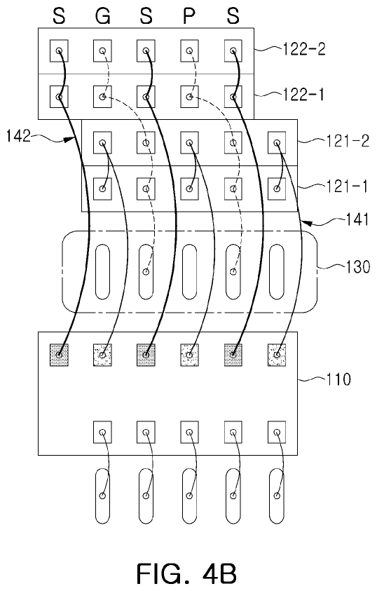

FIG. 6 is a diagram illustrating a nonvolatile memory package 100b according to another example embodiment. Referring to FIG. 6, in the nonvolatile memory package 100b, the signal pads of the second input/output pads PAD2 of the interface chip 110 may be connected to the signal pads S of the nonvolatile memory stack 122-2, instead of the nonvolatile memory stack 122-1, through the second channel bonding 142b as compared to the nonvolatile memory package 100 illustrated in FIG. 4A.

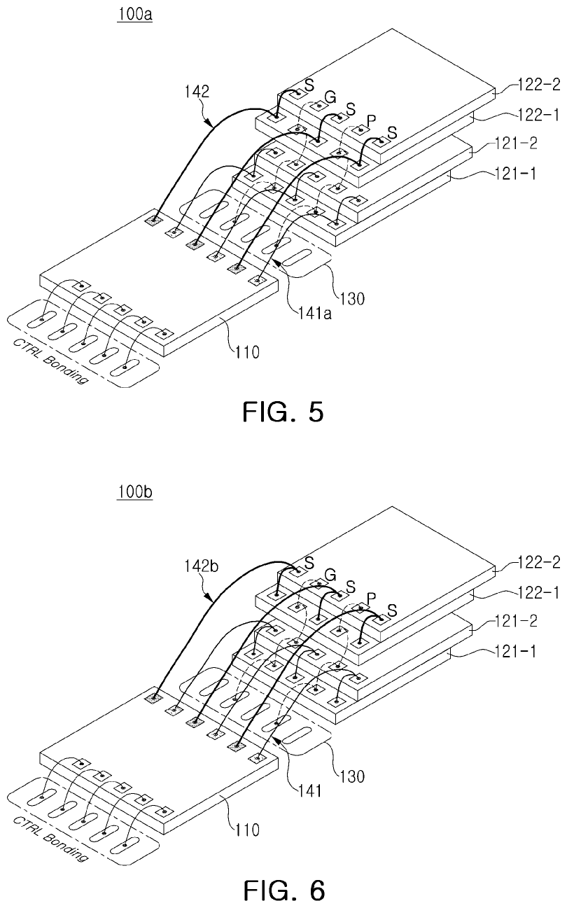

FIG. 7 is a diagram illustrating a nonvolatile memory package 100c according to another example embodiment. Referring to FIG. 7, in the nonvolatile memory package 100c, the signal pads of the first input/output pads PAD1 of the interface chip 110 may be connected to the signal pads S of the nonvolatile memory stack 121-1, rather than the nonvolatile memory stack 121-2 through the first channel bonding 141c, and the signal pads of the second input/output pads PAD2 of the interface chip 110 may be connected to the signal pads S of the nonvolatile memory stack 122-2, not the nonvolatile memory stack 122-1, through the second channel bonding 142c.

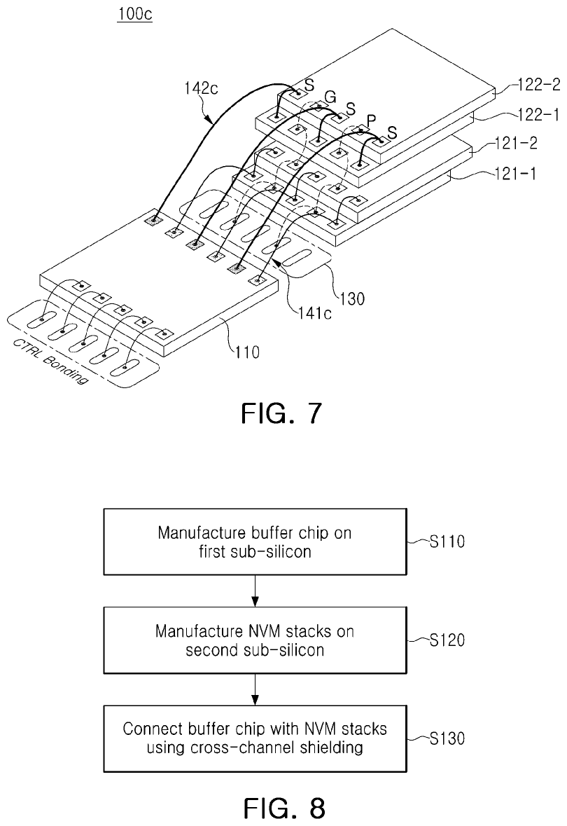

FIG. 8 is a flowchart illustrating a method of manufacturing a nonvolatile memory package according to an example embodiment. Referring to FIGS. 1 to 8, the manufacturing method of the nonvolatile memory package 100 may be performed as below.

A buffer chip (e.g., the interface chip 110) may be manufactured on the first sub-silicon substrate (S110). Nonvolatile memory stacks 120 may be manufactured on the second sub-silicon substrate (S120). On the package board, the buffer chip 110 and the nonvolatile memory stacks 120 may be connected to each other by bonding in a cross-channel shielding structure.

Meanwhile, a storage device according to an example embodiment may include nonvolatile memory packages connected to a controller through a plurality of channels.

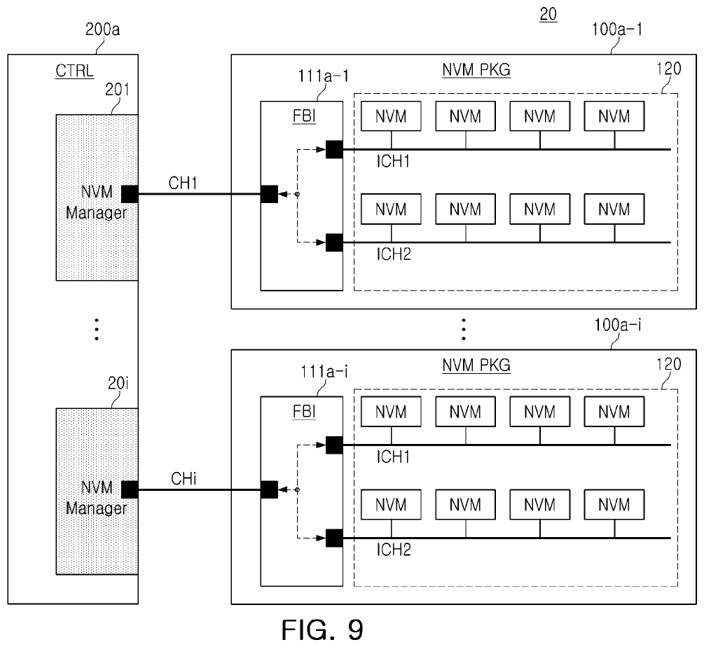

FIG. 9 is a diagram illustrating a storage device 20 according to another example embodiment. Referring to FIG. 9, the storage device 20 may include a plurality of nonvolatile memory packages 100a-1 and 100a-i (i is an integer greater than or equal to 2), and a controller 200a for controlling the nonvolatile memory packages.

The first nonvolatile memory package 100a-1 may be connected to the controller 200a by the first external channel (“fist bonding channel) CH1. The first nonvolatile memory package 100a-1 may be implemented in the same manner as the nonvolatile memory package 100 illustrated in FIG. 1. The other nonvolatile packages 100a-i may be implemented in the same manner as the nonvolatile memory package 100 illustrated in FIG. 1. In each of the nonvolatile memory packages 100a-1 and 100a-i, channel pads (or input/output pads) may be disposed with the cross-channel shielding structure described in FIGS. 1 to 8.

The controller 200a may include a plurality of nonvolatile memory managers (201, . . . , 20i). Each of the plurality of nonvolatile memory managers (201, . . . , 20i) may independently control the corresponding nonvolatile memory package (100a-1, . . . , 100a-i).

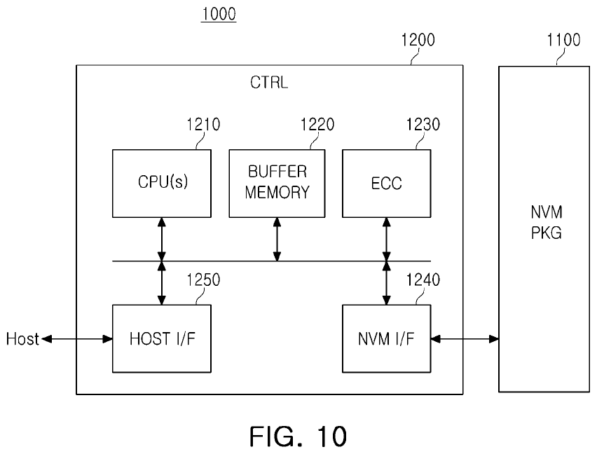

FIG. 10 is a diagram illustrating a storage device 1000 according to example embodiment. Referring to FIG. 10, a storage device 1000 may include at least one nonvolatile memory package 1100 NVM PKG and a controller 1200 CTRL.

At least one nonvolatile memory package 1100 NVM PKG may be implemented in the same manner as the nonvolatile memory package described in FIGS. 1 to 9. In an example embodiment, a nonvolatile memory device may optionally be implemented to receive an external high voltage Vpp.

The controller (1200; CTRL) may be connected to the nonvolatile memory package 1100 through a plurality of control pins that transmit control signals (e.g., CLE, ALE, CES, nWE, or nRE,). Also, the controller (1200; CTRL) may be implemented to control the nonvolatile memory package 1100 using control signals (CLE, ALE, CES, nWE, or nRE). For example, the nonvolatile memory package 1100 may perform program operation/read operation/erase operations by latching the command (CMD) or the address (ADD) at the edge of the write enable (WE) signal according to the command latch enable (CLE) signal and the address latch enable (ALE) signal. For example, during a read operation, the chip enable signal (CE) may be activated, CLE may be activated in the command transmission period, ALE may be activated in the address transmission period, and RE may be toggled in a section in which data is transmitted through a data signal line (DQ). The data strobe signal (DQS) may be toggled at a frequency corresponding to a data input/output speed. Read data may be transmitted in sequence in synchronization with the data strobe signal (DQS).

Also, the controller 1200 may be implemented to control overall operations of the storage device 1000. The controller 1200 may include at least one processor 1210 (CPUS, a buffer memory 1220, an error correction circuit 1230, a nonvolatile memory interface circuit 1240 and a host interface circuit 1240.

At least one processor 1210 (CPUS) may be implemented to control overall operations of the storage device 1000. The processor 1210 may perform various management tasks, such as cache/buffer management, firmware management, garbage collection management, wear leveling management, data deduplication management, read refresh/reclaim management, bad block management, multi-stream management, mapping management between host data and nonvolatile memory, quality of service (QoS) management, system resource allocation management, nonvolatile memory queue management, read level management, erase/program management, hot/cold data management, power loss protection management, dynamic thermal management, initialization management, and redundant array of inexpensive disk (RAID). These management operations may be implemented in terms of hardware/firmware/software. The buffer memory 1220 may be implemented to temporarily store data required for operation of the storage device 1000. For example, the buffer memory 1200 may temporarily store data to be written in the nonvolatile memory package 1100 or read data from the nonvolatile memory package 1100. In an example embodiment, the buffer memory 1220 may be configured to be included in the controller 1200. In another example embodiment, buffer memory 1220 may be disposed externally of the controller 1200. Also, the buffer memory 1220 may be implemented as a volatile memory (e.g. Static Random Access Memory (SRAM), dynamic RAM (DRAM), synchronous RAM (SDRAM), or the like) or a nonvolatile memory (flash memory, phase-change RAM (PRAM)), Magneto-resistive RAM (MRAM), Resistive RAM (ReRAM), Ferro-electric RAM (FRAM), or the like).

The error correction circuit 1230 may be implemented to generate an error correction code ECC during a program operation and may recover data using the error correction code during a read operation. That is, the error correction circuit 1230 may generate an error correction code ECC for correcting a failure bit or error bit of data received from the nonvolatile memory package 1100. Also, the error correction circuit 1230 may form data to which parity bits are added by performing error correction encoding on data provided to the nonvolatile memory package 1100. Parity bits may be stored in the nonvolatile memory package 1100. Also, the error correction circuit 1230 may perform error correction decoding on data output from the nonvolatile memory package 1100. The error correction circuit 1230 may correct errors using parity. The error correction circuit (1230) may correct an error using a low-density parity check (LDPC) code, BCH code, turbo code, Reed-Solomon code, convolution code, recursive systematic code (RSC), and coded modulation such as trellis-coded modulation (TCM), and block coded modulation (BCM). When error correction is impossible in the error correction circuit 1230, a read retry operation may be performed.

The nonvolatile memory interface circuit 1240 (NIF) may exchange data through a plurality of pins described in at least one nonvolatile memory package 1100. The nonvolatile memory interface circuit 1240 may transmit data to be written in the nonvolatile memory package 1100 to the nonvolatile memory package 1100 or may receive read data from the nonvolatile memory package 1100. The memory interface circuit 1240 may be implemented to comply with standard protocols such as JEDEC Toggle or ONFI.

The host interface circuit 1250 (HIF) may be implemented to provide a host device and interface function. The host interface circuit 1250 may be implemented to transmit packets to and receive packets from the host. A packet transmitted from the host to the host interface circuit 250 may include a command or write data to the nonvolatile memory package 1100. A packet transmitted from the host interface circuit 1250 to the host may include a response to a command or read data from the nonvolatile memory package 1100.

The controller 1200 may further include an encryption device to improve information protection. The encryption device may perform at least one of an encryption operation and a decryption operation on data input to the controller 1200 using a symmetric-key algorithm. The encryption device may perform encryption and decryption of data using an advanced encryption standard (AES) algorithm. The encryption device may include an encryption module and a decryption module. In an example embodiment, the encryption device may be implemented in terms of hardware/software/firmware. The encryption device may perform a self-encryption disk (SED) function or a trusted computing group (TCG) security function. The SED function may store encrypted data in the nonvolatile memory package 1100 using an encryption algorithm or may decrypt encrypted data from the nonvolatile memory package 1100. The encryption/decryption operation may be performed using an internally generated encryption key. The TCG security function may provide a mechanism enabling access control to user data of the storage device 1000. For example, the TCG security function may perform an authentication procedure between an external device and the storage device 1000. In an example embodiment, the SED function or TCG security function may be optionally selected.

The nonvolatile memory device NVM according to example embodiment may be implemented as a vertical memory device.

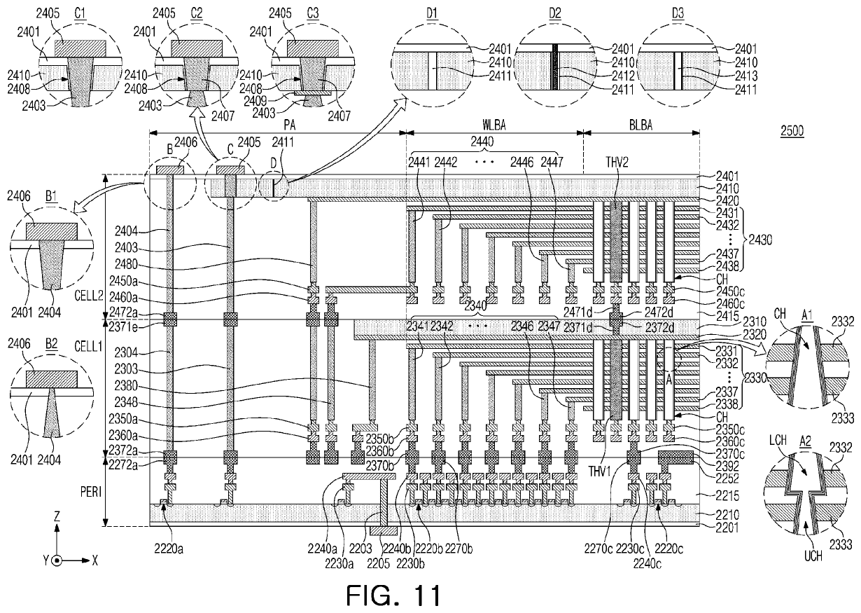

FIG. 11 is a diagram illustrating a nonvolatile memory device according to an example embodiment. Referring to FIG. 11, the nonvolatile memory device 2500 may have a chip to chip (C2C) structure. Here, the C2C structure may include manufacturing at least one upper chip including a cell region CELL and a lower chip including a peripheral circuit region PERI, respectively, and connecting at least one upper chip and lower chip to each other by bonding. In an example embodiment, the bonding method may refer to a method of electrically or physically connecting the bonding metal pattern formed on the uppermost metal layer of the upper chip to the bonding metal pattern formed on the uppermost metal layer of the lower chip. For example, when the bonding metal patterns are formed of copper (Cu), the bonding method may be a Cu-Cu bonding method. In another example embodiment, bonding metal patterns may also be formed of aluminum (Al) or tungsten (W).

The nonvolatile memory device 2500 may include at least one upper chip including a cell region. For example, as illustrated in FIG. 11, a nonvolatile memory device 2500 may be implemented to include two upper chips. However, this is merely an example, and the number of upper chips is not limited thereto. When the nonvolatile memory device 2500 is implemented to include two upper chips, the nonvolatile memory device 2500 may be manufactured by manufacturing a first upper chip including a first cell region CELL1, a second upper chip including a second cell region CELL2 and a lower chip including a peripheral circuit region PERI, respectively, and connecting the first upper chip, the second upper chip and the lower chip to each other by bonding. The first upper chip may be inverted and connected to the lower chip by bonding, and the second upper chip may also be inverted and connected to the first upper chip by bonding. In the description below, the upper portion and the lower portion of the first and second upper chips may be defined with respect to the state before the first upper chip and the second upper chip are inverted. That is, in FIG. 11, the upper portion of the lower chip may refer to the upper portion defined in the +Z-axis direction, and the upper portion of each of the first and second upper chips may refer to the upper portion defined in the −Z-axis direction. However, this is merely an example, and only one of the first upper chip and the second upper chip may be inverted and connected to each other by bonding.

Each of the peripheral circuit region PERI and the first and second cell regions CELL1 and CELL2 of the nonvolatile memory device 2500 may include an external pad bonding region PA, a wordline bonding region WLBA, and a bitline bonding region BLBA.

The peripheral circuit region PERI may include a first board 2210 and a plurality of circuit devices 2220a, 2220b, and 2220c formed on the first board 2210. An interlayer insulating layer 2215 including one or more insulating layers may be provided on the plurality of circuit devices 2220a, 2220b, and 2220c, and a plurality of metal wirings may be provided in the interlayer insulating layer 2215 to connect the plurality of circuit devices 2220a, 2220b, and 2220c. For example, the plurality of metal wirings may include first metal wirings 2230a, 2230b, and 2230c connected to a plurality of circuit devices 2220a, 2220b, and 2220c, and second metal wirings 2240a, 2240b, and 2240c formed on first metal wirings 2230a, 2230b, and 2230c. The plurality of metal wirings may be formed of at least one of various conductive materials. For example, the first metal wirings 2230a, 2230b, and 2230c may be formed of tungsten having relatively high electrical resistivity, and the second metal wirings 2240a, 2240b, and 2240c may be formed of copper having relatively low electrical resistivity.

Here, only the first metal wiring 2230a, 2230b, and 2230c and the second metal wiring 2240a, 2240b, and 2240c are described, but an example embodiment thereof is not limited thereto, and at least one additional metal wiring may be further formed on the second metal wirings 2240a, 2240b, and 2240c. In this case, the second metal wirings 2240a, 2240b, and 2240c may be formed of aluminum. Also, at least a portion of the additional metal wiring formed on the second metal wirings 2240a, 2240b, and 2240c may be formed of copper having lower electrical resistivity than that of aluminum of the second metal wirings 2240a, 2240b, and 2240c.

The interlayer insulating layer 2215 may be disposed on the first board 2210 and may include an insulating material such as silicon oxide or silicon nitride.

Each of the first and second cell regions CELL1 and CELL2 may include at least one memory block. The first cell region CELL1 may include a second board 2310 and a common source line 2320. On the second board 2310, a plurality of wordlines 2331 to 2338 (2330) may be stacked in the direction (Z-axis direction) perpendicular to the upper surface of the second board 2310. String selection lines and ground selection lines may be disposed above and below the wordlines 2330, and a plurality of wordlines 2330 may be disposed between the string selection lines and the ground selection line. Similarly, the second cell region CELL2 may include a third board 2410 and a common source line (2420), and a plurality of wordlines 2431 to 2438 (2430) may be stacked in a direction (Z-axis direction) perpendicular to the upper surface of the third board 2410. The second board 2310 and the third board 2410 may be formed of various materials, for example, a board having a single crystal epitaxial layer grown on a silicon board, a silicon-a germanium board, a germanium board, or a monocrystalline silicon board. A plurality of channel structures CHs may be formed in each of the first and second cell regions CELL1 and CELL2.

As illustrated in an example embodiment, A1, the channel structure CH may be provided in the bitline bonding region BLBA, may extend in a direction perpendicular to the upper surface of the second board 2310 and may penetrate through the wordlines 2330, string selection lines, and ground selection lines. The channel structure CH may include a data storage layer, a channel layer, and a buried insulating layer. The channel layer may be electrically connected to the first metal wiring 2350c and the second metal wiring 2360c in a bitline bonding region BLBA. For example, the second metal wiring 2360c may be a bitline and may be connected to the channel structure CH through the first metal wiring 2350c. The bitline 2360c may extend in a first direction (Y-axis direction) parallel to the upper surface of the second board 2310.

In an example embodiment, as illustrated in A2, the channel structure CH may include a lower channel LCH and an upper channel UCH connected to each other. For example, the channel structure CH may be formed through a process for a lower channel LCH and a process for an upper channel UCH. The lower channel LCH may extend in a direction perpendicular to the upper surface of the second board 2310 and may penetrate through the common source line 2320 and the lower wordlines 2331 and 2332. The lower channel LCH may include a data storage layer, a channel layer and a buried insulating layer, and may be connected to an upper channel UCH. The upper channel UCH may penetrate through upper wordlines 2333-2338. The upper channel UCH may include a data storage layer, a channel layer and a buried insulating layer, and the channel layer of the upper channel UCH may be electrically connected to the first metal wiring 2350c and the second metal wiring 2360c. As the length of the channel increases, it may be difficult to form a channel having a constant width due to reasons related to processes. The nonvolatile memory device 2500 according to the example embodiment may include a channel having improved width uniformity through a lower channel LCH and an upper channel UCH formed through sequential processes.

As illustrated in A2, when the channel structure CH is formed to include a lower channel LCH and an upper channel UCH, a wordline disposed neighboring to the boundary of the lower channel LCH and the upper channel UCH may be a dummy wordline. For example, the wordline 2332 and the wordline 2333 forming the boundary between the lower channel LCH and the upper channel UCH may be dummy wordlines. In this case, data may not be stored in the memory cells connected to the dummy wordline. Alternatively, the number of pages corresponding to memory cells connected to a dummy wordline may be less than the number of pages corresponding to memory cells connected to a general wordline. The voltage level applied to the dummy wordline may be different from the voltage level applied to the general wordline, and accordingly, the effect of the non-uniform channel width between the lower channel LCH and the upper channel UCH on the operation of the memory device may be reduced.

Meanwhile, in A2, the number of lower wordlines 2331 and 2332 through which the lower channel LCH penetrates may be less than the number of upper wordlines 2333-2338 through which the upper channel UCH penetrates. However, this is merely an example, and an example embodiment thereof is not limited thereto. In another example embodiment, the number of lower wordlines penetrating through the lower channel LCH may be equal to or greater than the number of upper wordlines penetrating through the upper channel UCH. Also, the structure and connection relationship of the channel structure CH disposed in the first cell region CELL1 described above may be applied to the channel structure CH disposed in the second cell region CELL2.

In the bitline bonding region BLBA, a first through-electrode THV1 may be provided in a first cell region CELL1, and a second through-electrode THV2 may be provided in a second cell region CELL2. As illustrated in FIG. 11, a first through-electrode THV1 may penetrate through a common source line 2320 and a plurality of wordlines 2330. However, this is merely an example, and the first through-electrode THV1 may further penetrate through the second board 2310. The first through-electrode THV1 may include a conductive material. Alternatively, the first through-electrode THV1 may include a conductive material surrounded by an insulating material. The second through-electrode THV2 may also be provided in the same form and structure as those of the first through-electrode THV1.

In an example embodiment, the first through-electrode THV1 and the second through-electrode THV2 may be electrically connected through a first through-metal pattern 2372d and a second through-metal pattern 2472d. The first through-metal pattern 2372d may be formed on the lower end of the first upper chip including the first cell region CELL1, and the second through-metal pattern 2472d may be formed on the upper end of the second upper chip including the second cell region CELL2. The first through-electrode THV1 may be electrically connected to the first metal wiring 2350c and the second metal wiring 2360c. A lower via 2371d may be formed between the first through-electrode THV1 and the first through-metal pattern 2372d, and an upper via 2471d may be formed between the second through-electrode THV2 and the second through-metal pattern 2472d. The first through-metal pattern 2372d and the second through-metal pattern 2472d may be connected to each other by bonding.

Also, in the bitline bonding region BLBA, an upper metal pattern 2252 may be formed on the uppermost metal layer of the peripheral circuit region PERI, and an upper metal pattern 2392 having the same shape as that of the upper metal pattern 2252 may be formed in the uppermost metal layer of the first cell region CELL1. The upper metal pattern 2392 of the first cell region CELL1 and the upper metal pattern 2252 of the peripheral circuit region PERI may be electrically connected to each other by bonding. In the bitline bonding region BLBA, the bitline 2360c may be electrically connected to a page buffer included in the peripheral circuit region PERI. For example, a portion of the circuit devices 2220c of the peripheral circuit region PERI may provide a page buffer, and the bitline 2360c may be electrically connected to circuit devices 2220c providing a page buffer through the upper bonding metal 2370c of the first cell region CELL1 and the upper bonding metal 2270c of the peripheral circuit region PERI.

Referring to FIG. 11, in the wordline bonding region WLBA, the wordlines 2330 of the first cell region CELL1 may extend in a second direction (X-axis direction) parallel to the upper surface of the second board 2310 and may be connected to a plurality of cell contact plugs 340 (2341-347). A first metal wiring 2350b and a second metal wiring 2360b may be connected in sequence to an upper portion of the cell contact plugs 2340 connected to the wordlines 2330. The cell contact plugs 2340 may be connected to the peripheral circuit region PERI through the upper bonding metal 2370b of the first cell region CELL1 and the upper bonding metal 2270b of the peripheral circuit region PERI in the wordline bonding region WLBA.

The cell contact plugs 2340 may be electrically connected to a row decoder included in a peripheral circuit region PERI. For example, a portion of the circuit devices 2220b of the peripheral circuit region PERI may provide a row decoder, and the cell contact plugs 2340 may be electrically connected to the circuit devices 2220b providing the row decoder through the upper bonding metal 2370b of the first cell region CELL1 and the upper bonding metal 2270b of the peripheral circuit region PERI. In an example embodiment, an operation voltage of the circuit devices 2220b providing a row decoder may be different from an operation voltage of the circuit devices 2220c providing a page buffer. For example, an operation voltage of the circuit devices 2220c providing a page buffer may be higher than an operation voltage of the circuit devices 2220b providing a row decoder.

Similarly, in the wordline bonding region WLBA, the wordlines 2430 of the second cell region CELL2 may extend in the second direction (X-axis direction) parallel to the upper surface of the third board 2410, and may be connected to a plurality of cell contact plugs 2440 (2441-2447). The cell contact plugs 2440 may be connected to the peripheral circuit region PERI through an upper metal pattern of the second cell region CELL2, a lower metal pattern and an upper metal pattern of the first cell region CELL1, and a cell contact plug 2348.

In the wordline bonding region WLBA, an upper bonding metal 2370b may be formed in a first cell region CELL1, and an upper bonding metal 2270b may be formed in a peripheral circuit region PERI. The upper bonding metal 2370b of the first cell region CELL1 and the upper bonding metal 2270b of the peripheral circuit region PERI may be electrically connected to each other by bonding. The upper bonding metal 2370b and the upper bonding metal 2270b may be formed of aluminum, copper, or tungsten.

In the external pad bonding region PA, a lower metal pattern 2371e may be formed in the lower portion of the first cell region CELL1, and an upper metal pattern (2472a) may be formed in the upper portion of the second cell region CELL2. The lower metal pattern 2371e of the first cell region CELL1 and the upper metal pattern 2472a of the second cell region CELL2 may be connected to each other by bonding in the external pad bonding region PA. Similarly, an upper metal pattern 2372a may be formed on the first cell region CELL1, and an upper metal pattern 2272a may be formed on the peripheral circuit region PERI. The upper metal pattern 2372a of the first cell region CELL1 and the upper metal pattern 2272a of the peripheral circuit region PERI may be connected to each other by bonding.

Common source line contact plugs 2380 and 2480 may be disposed in the external pad bonding region PA. The common source line contact plugs 2380 and 2480 may be formed of a conductive material such as metal, metal compound, or doped polysilicon. The common source line contact plug 2380 of the first cell region CELL1 may be electrically connected to the common source line 2320, and the common source line contact plug 2480 of the second cell region CELL2 may be electrically connected to the common source line 2420. A first metal wiring 2350a and a second metal wiring (2360a) may be stacked in sequence on the common source line contact plug 2380 of the first cell region CELL1, and a first metal wiring 2450a and a second metal wiring 2460a may be stacked in sequence on the common source line contact plug 2480 of the second cell region CELL2.

The input/output pads 2205, 2405, and 2406 may be disposed in the external pad bonding region PA. Referring to FIG. 11, a lower insulating film 2201 may cover the lower surface of the first board 2210, and a first input/output pad 2205 may be formed on the lower insulating film 2201. The first input/output pad 2205 may be connected to at least one of the plurality of circuit devices 2220a disposed in the peripheral circuit region PERI through the first input/output contact plug 2203 and may be isolated from the first board 2210 by a lower insulating film 2201. Also, a side insulating film may be disposed between the first input/output contact plug 2203 and the first board 2210 and may electrically isolate the first input/output contact plug 2203 and the first board 2210 from each other.

An upper insulating film 2401 covering an upper surface of the third board 2410 may be formed above the third board 2410. A second input/output pad 2405 or a third input/output pad 2406 may be disposed on the upper insulating film 2401. The second input/output pad 2405 may be connected to at least one of a plurality of circuit devices 2220a disposed in the peripheral circuit region PERI through the second input/output contact plugs 2403 and 2303, and the third input/output pad 2406 may be connected to at least one of the plurality of circuit devices 2220a arranged in the peripheral circuit region PERI through the third input/output contact plugs 2404 and 2304.

In an example embodiment, the third board 2410 may not be disposed in a region in which an input/output contact plug is disposed. For example, as illustrated in B, the third input/output contact plug 2404 may be isolated from the third board 2410 in a direction parallel to the upper surface of the third board 2410, and may penetrate through the interlayer insulating layer 2415 of the second cell region CELL2 and may be connected to the third input/output pad 2406. In this case, the third input/output contact plug 2404 may be formed through various processes.

For example, as illustrated in B1, the third input/output contact plug 2404 may extend in the third direction (Z-axis direction) and may have a diameter increasing toward the upper insulating film 2401. That is, while the diameter of the channel structure CH described in A1 is formed to decrease toward the upper insulating film 2401, the diameter of the third input/output contact plug 2404 may increase toward the upper insulating film 2401. For example, the third input/output contact plug 2404 may be formed after the second cell region CELL2 and the first cell region CELL1 are bonded to each other.

Also, as an example, as illustrated in B2, the third input/output contact plug 2404 may extend in the third direction (Z-axis direction) and may have a diameter decreasing toward the upper insulating film 2401. That is, the diameter of the third input/output contact plug 2404 may decrease toward the upper insulating film 2401 similarly to the channel structure CH. For example, the third input/output contact plug 2404 may be formed together with the cell contact plugs 2440 before the second cell region CELL2 and the first cell region CELL1 are bonded to each other.

In another example embodiment, an input/output contact plug may be disposed to overlap the third board 2410. For example, as illustrated in C, the second input/output contact plug 2403 may be formed by penetrating through the interlayer insulating layer 2415 of the second cell region CELL2 in the third direction (Z-axis direction), and may be electrically connected to the second input/output pad 2405 through the third board 2410. In this case, the connection structure of the second input/output contact plug 2403 and the second input/output pad 2405 may be implemented in various manners.

For example, as illustrated in C1, an opening 2408 penetrating through the third board 2410 may be formed, and the second input/output contact plug 2403 may be directly connected to the second input/output pad 2405 through an opening 2408 formed in the third board 2410. In this case, as illustrated in C1, the diameter of the second input/output contact plug 2403 may increase toward the second input/output pad 2405. However, this is merely an example, and the diameter of the second input/output contact plug 2403 may decrease toward the second input/output pad 2405.

For example, as illustrated in C2, an opening 2408 penetrating through the third board 2410 may be formed, and a contact 2407 may be formed in the opening 2408. One end of the contact 2407 may be connected to the second input/output pad 2405, and the other end may be connected to the second input/output contact plug 2403. Accordingly, the second input/output contact plug 2403 may be electrically connected to the second input/output pad 2405 through the contact 2407 in the opening 2408. In this case, as illustrated in C2, the diameter of the contact 2407 may increase toward the second input/output pad 2405, and the diameter of the second input/output contact plug 2403 may decrease toward the second input/output pad 2405. For example, the third input/output contact plug 2403 may be formed together with the cell contact plugs 2440 before the second cell region CELL2 and the first cell region CELL1 are bonded to each other, and the contact 2407 may be formed after the second cell region CELL2 and the first cell region CELL1 are bonded to each other.

Also, as an example, as illustrated in C3, a stopper 2409 may be further formed on the upper surface of the opening 2408 of the third board 2410 as compared to C2. The stopper 2409 may be metal wiring formed on the same layer as the common source line 2420. However, this is merely an example, and the stopper 2409 may be metal wiring formed on the same layer as at least one of the wordlines 2430. The second input/output contact plug 2403 may be electrically connected to the second input/output pad 2405 through the contact 2407 and the stopper 2409.

Similarly, to the second and third input/output contact plugs 2403 and 2404 of the second cell region CELL2, the second and third input/output contact plugs 2303 and 2304 of the first cell region CELL1 may have a diameter decreasing toward the lower metal pattern 2371e or a diameter increasing toward the lower metal pattern 2371e, respectively.

In example embodiments, a slit 411 may be formed on the third board 2410. For example, the slit 2411 may be formed in an arbitrary position of the external pad bonding region PA. In an example embodiment, as illustrated D, the slit 2411 may be disposed between the second input/output pad 2405 and the cell contact plugs 2440 when viewed from a plane. However, this is merely an example, and the slit 2411 may be formed such that the second input/output pad 2405 may be disposed between the slit 2411 and the cell contact plugs 2440 when viewed from a plane.

For example, as illustrated in D1, the slit 2411 may be formed to penetrate through the third board 2410. The slit 2411 may be used to prevent the third board 2410 from being finely split when the opening 2408 is formed. However, this is merely an example, and the slit 2411 may be formed to a depth of about 60-70% of the thickness of the third board 2410.

Also, as an example, as illustrated in D2, a conductive material 2412 may be formed in the slit 2411. The conductive material 2412 may be used, for example, to discharge leakage current generated during driving of circuit devices in an external pad bonding region PA. In this case, the conductive material 2412 may be connected to an external ground line.

As an example, as illustrated in D3, an insulating material 2413 may be formed in the slit 2411. The insulating material 2413 may electrically isolate the second input/output pad 2405 and the second input/output contact plug 2403 disposed in the external pad bonding region PA from the wordline bonding region WLBA, for example. By forming the insulating material 2413 in the slit 2411, the voltage provided through the second input/output pad 2405 may be prevented from affecting the metal layer disposed on the third board 2410 in the wordline bonding region WLBA.

In example embodiments, first to third input/output pads 2205, 405, and 406 may be selectively formed. For example, the nonvolatile memory device 2500 may include only the first input/output pad 2205 disposed above the first board 2201, may include only the second input/output pad 2405 disposed above the third board 2410, or may include only the third input/output pad 2406 disposed above the upper insulating film 2401.

In example embodiments, at least one of the second board 2310 of the first cell region CELL1 and the third board 2410 of the second cell region CELL2 may be used as a sacrificial board, and may be completely or partially removed before or after the bonding process. An additional film may be deposited after removing the board. For example, the second board 2310 of the first cell region CELL1 may be removed before or after bonding between the peripheral circuit region PERI and the first cell region CELL1, and an insulating film covering the upper surface of the common source line 2320 or a conductive film for connection may be formed. Similarly, the third board 2410 of the second cell region CELL2 may be removed before or after bonding between the first cell region CELL1 and the second cell region CELL2, and an upper insulating film 2401 covering the upper surface of the common source line 2420 or a conductive film for connection may be formed.

The storage device according to example embodiment may be applicable to a data server system.

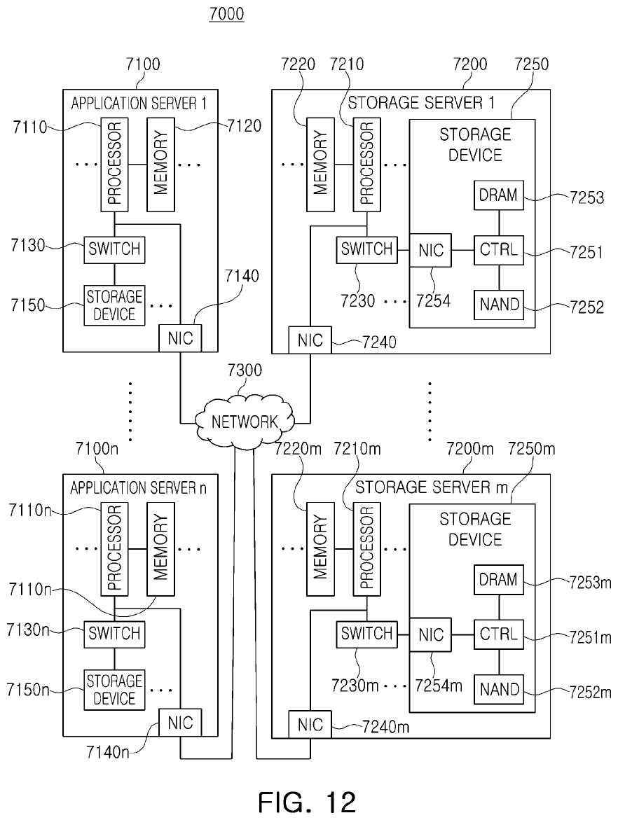

FIG. 12 is a diagram illustrating a data center to which a memory device according to an example embodiment. Referring to FIG. 12, a data center 7000 may include application servers 7100 to 7100n and storage servers 7200 to 7200m. The number of application servers 7100 to 7100n and the number of storage servers 7200 to 7200m may be variously selected in example embodiments, and the number of application servers 7100 to 7100n and the number of storage servers 7200 to 7200m may be different.

The application server 7100 or the storage server 7200 may include at least one of processors 7110 and 7210 and memory 7120 and 7220. For example, as for the storage server 7200, the processor 7210 may control overall operations of the storage server 7200, may access the memory 7220, and may execute commands or data loaded into the memory 7220. The memory 7220 may be implemented as a DDR double data rate synchronous DRAM (SDRAM), high bandwidth memory (HBM), hybrid memory cube (HMC), dual in-line memory Module (DIMM), Optane DIMM, or non-volatile DIMM (NVMDIMM). In example embodiments, the number of processors 7210 and the number of memories 7220 included in the storage server 7200 may be variously selected. In an example embodiment, the processor 7210 and the memory 7220 may provide a processor-memory pair. In the example embodiment, the number of processors 7210 and the number of memories 7220 may be different. The processor 7210 may include a single-core processor or a multi-core processor. The description of the storage server 7200 may be similarly applied to the application server 7100. In example embodiments, the application server 7100 may not include the storage device 7150. The storage server 7200 may include at least one storage device 7250. The number of storage devices 7250 included in the storage server 7200 may be variously selected in example embodiments.

Application servers 7100 to 7100n and the storage servers 7200 to 7200m may communicate with each other through the network 7300. The network 7300 may be implemented using fiber channel (FC) or Ethernet. In this case, FC may be a medium used for relatively high-speed data transmission, and may use an optical switch providing high performance/high availability. Depending on the access method of the network 7300, the storage servers 7200 to 7200m may be provided as file storage media, block storage media, or object storage media.

In an example embodiment, the network 7300 may be a storage network, such as a storage area network (SAN). For example, the SAN may be an FC-SAN using an FC network and implemented according to FC Protocol (FCP). As another example, the SAN may be an IP-SAN using a TCP/IP network and implemented according to the iSCSI (SCSI over TCP/IP or Internet SCSI) protocol. In another example embodiment, network 7300 may be a generic network, such as a TCP/IP network. For example, the network 7300 may be implemented according to protocols such as FC over Ethernet (FCoE), network attached storage (NAS), and NVMe over fabrics (NVMe-oF). The description of the application server 7100 may be applied to other application servers 7100n, and the description of the storage server 7200 may also be applied to other storage servers 7200m.

The application server 7100 may store data requested by a user or client to be stored in one of storage servers 7200 to 7200m through the network 7300. Also, the application server 7100 may obtain data read-requested by a user or a client from one of the storage servers 7200 to 7200m through the network 7300. For example, the application server 7100 may be implemented as a web server or a database management system (DBMS).

The application server 7100 may access the memory 7120n or the storage device 7150n included in another application server 7100n through the network 7300, or may access the memory 7220-7220m or the storage device 7250-7250m included in the storage server 7200-7200m through the network 7300. Accordingly, the application server 7100 may perform various operations on data stored in the application servers 7100-7100n or the storage servers 7200-7200m. For example, the application server 7100 may execute a command for moving or copying data between the application servers 7100-7100n or the storage servers 7200-7200m. In this case, the data may move from the storage device 7250-7250m of the storage servers 7200-7200m to the memories 7220-7220m of the storage servers 7200-7200m, or may directly move to the memories 7120-7120n of the application servers 7100-7100n. The data moving through the network 7300 may be encrypted data for security or privacy.

For example, in the storage server 7200, the interface 7254 may provide a physical connection between the processor 7210 and the controller 7251 and a physical connection between the NIC 7240 and the controller 7251. For example, the interface 7254 may be implemented in a direct attached storage (DAS) method of directly connecting the storage device 7250 using a dedicated cable. Also, for example, the interface 1254 may be implemented by various interface method such as advanced technology attachment (ATA), serial ATA (SATA), external SATA (e-SATA), small computer small interface (SCSI), serial attached SCSI (SAS), peripheral component interconnection (PCI), PCI express (PCIe), NVMe (NVM express), IEEE 1394, universal serial bus (USB), secure digital (SD) card, multi-media card (MMC), embedded multi-media card (eMMC), universal flash storage (UFS), embedded universal (eUFS) flash Storage), or compact flash (CF) card interface.

The storage server 7200 may further include a switch 7230 and a NIC 7240. The switch 7230 may selectively connect the processor 7210 to the storage device 7250 or may selectively connect the NIC 7240 to the storage device 7250 under control of the processor 7210.

In an example embodiment, the NIC 7240 may include a network interface card, and a network adapter. The NIC 7240 may be connected to the network 7300 through a wired interface, a wireless interface, a Bluetooth interface, or an optical interface. The NIC 7240 may include an internal memory, DSP, and a host bus interface, and may be connected to the processor 7210 or a switch 7230 through the host bus interface. The host bus interface may be implemented as one of the examples of interface 7254 described above. In the example embodiment, the NIC 7240 may be integrated with at least one of the processor 7210, the switch 7230, and the storage device 7250.

The processor in the storage server 7200-7200m or the application server 7100-7100n may transmit a command to the storage device 7130-7130n and 7250-7250m or the memory 7120-7120n and 7220-7220m and may program or read the data. In this case, the data may be error-corrected data, an error of which may be corrected through an error correction code ECC engine. Data may be data bus inversion (DBI) or data masking (DM) processed data, and may include cyclic redundancy code (CRC) information. The data may be encrypted data for security or privacy.

The storage devices 7150-7150m and 7250-7250m may transmit a control signal and a command/address signal to the NAND flash memory devices 7252-7252m in response to a read command received from the processor. Accordingly, when data is read from the NAND flash memory devices 7252-7252m, a read enable (RE) signal may be input as a data output control signal, and may output data to the DQ bus. A data strobe (DQS) may be generated using the RE signal. Command and address signals may be latched in the page buffer according to a rising edge or a falling edge of the write enable (WE) signal.

In an example embodiment, the storage devices 7150-7150m and 7250-7250m may include a nonvolatile memory package implemented as a cross-channel shielding structure as described in FIGS. 1 to 11.

The controller 7251 may control overall operation of the storage device 7250. In an example embodiment, the controller 7251 may include a static random access memory (SRAM). The controller 7251 may write data to the NAND flash 7252 in response to a write command, or may read data from the NAND flash 7252 in response to a read command. For example, a write command or a read command may be provided from the processor 7210 in the storage server 7200, the processor 7210m in the other storage server 7200m, or the processor 7110 or 7110n in the application server 7100 or 7100n. The DRAM 7253 may temporarily store (buffer) data to be written to the NAND flash 7252 or data read from the NAND flash 7252. Also, the DRAM 7253 may store metadata. Here, the metadata may be user data or data generated by the controller 7251 to manage the NAND flash 7252.

The device described above may be implemented as a hardware component, a software component, and/or a combination of hardware components and software components. For example, the devices and the components described in the example embodiment may include a processor, a controller, an arithmetic logic unit (ALU), a digital signal processor, a microcomputer, a field programmable gate array (FPGA), and a programmable logic unit (PLU), a microprocessor, or any other device for executing and responding to instructions. The processing device may execute an operating system (OS) and one or more software applications executing on the operating system. Also, the processing device may access, store, manipulate, process and create data in response to execution of software. For ease of description, a single processing device may be used, but the processing device may include a plurality of processing elements or a plurality of types of processing elements. For example, a processing device may include a plurality of processors or a processor and a controller. Other processing configurations may also be included, such as parallel processors.

Software may include a computer program, codes, instructions, or a combination of one or more thereof, and configure processing devices to operate as desired or command processing devices independently or collectively. Software and/or data may be any tangible machine, component, physical device, virtual device, computer storage medium or device in order to be interpreted by or to provide instructions or data to a processing device. Software may be distributed on networked computer systems and may be stored or executed in a distributed manner. Software and data may be stored on one or more computer readable recording media.

Aspects of the present invention disclose a non-volatile memory system with an Input/Output Buffer designed to improve high-speed signal characteristics. Aspects of the invention include an I/O Buffer and an NVM (non-volatile memory) stack, with alternating arrangement of different channel PADs within the I/O Buffer towards the NVM, which may attenuate cross-talk. Aspects of the invention may enhance signal integrity due to the reduction in cross-talk. By arranging Channel 1 and Channel 2 on the same line and alternating the placement of DQ across channels, cross-talk may be further attenuated.

A non-volatile memory package, a storage device having the same, and a manufacturing method thereof may increase the flexibility of package development while reducing chip size by arranging channel pads with a cross-channel shielding structure.

While the example embodiments have been illustrated and described above, it will be configured as apparent to those skilled in the art that modifications and variations could be made without departing from the scope of the present disclosure as defined by the appended claims.

What is claimed is:

1. A nonvolatile memory package, comprising:
first nonvolatile memory devices configured to be stacked;
second nonvolatile memory devices configured to be stacked; and
an interface chip connected to an external device through a bonding channel, connected to one of the first nonvolatile memory devices through a first bonding channel, and connected to one of the second nonvolatile memory devices through a second bonding channel, wherein the interface chip includes:
input/output pads connected to the bonding channel;
first input/output pads connected to the first bonding channel; and
second input/output pads connected to the second bonding channel, wherein the first input/output pads and the second input/output pads are alternately arranged by channel for cross-channel shielding.

2. The nonvolatile memory package of claim 1, wherein the first input/output pads and the second input/output pads are arranged in a single row or in a zigzag pattern.

3. The nonvolatile memory package of claim 1,
wherein each of the first nonvolatile memory devices includes first signal pads connected to each other, first ground pads connected to each other, and first power pads connected to each other, and
wherein each of the second nonvolatile memory devices includes second signal pads connected to each other, second ground pads connected to each other, and second power pads connected to each other.

4. The nonvolatile memory package of claim 3,
wherein one of the first ground pads and the first power pads is alternately arranged between the first signal pads, and
wherein one of the second ground pads and the second power pads is alternately arranged between the second signal pads.

5. The nonvolatile memory package of claim 3,
wherein the one of the first ground pad is connected to the one of the second ground pad, and
wherein the one of the first power pad is connected to the one of the second power pad.

6. The nonvolatile memory package of claim 5, wherein the first ground pad and the first power pad are connected to bonding pads connected to the external device.

7. The nonvolatile memory package of claim 1, wherein the input/output pads are arranged in a row.

8. The nonvolatile memory package of claim 1, wherein, when one of the first bonding channel and the second bonding channel is activated, the other is inactivated.

9. The nonvolatile memory package of claim 1, wherein the first bonding channel is connected to a lowermost nonvolatile memory device among the first nonvolatile memory devices or is connected to an uppermost nonvolatile memory device among the first nonvolatile memory devices.

10. The nonvolatile memory package of claim 1, wherein the second bonding channel is connected to a lowermost nonvolatile memory device among the second nonvolatile memory devices or connected to an uppermost nonvolatile memory device among the second nonvolatile memory devices.

11. A storage device, comprising:
a nonvolatile memory package; and
a controller connected to the nonvolatile memory package through a channel and configured to control the nonvolatile memory package,
wherein the nonvolatile memory package includes:
first nonvolatile memory devices connected to a first internal channel;
second nonvolatile memory devices connected to a second internal channel;
an interface chip connected to the first internal channel and the second internal channel,
wherein the interface chip includes:
input/output pads disposed in a first row and connected to the channel;
first input/output pads connected to the first internal channel; and
second input/output pads connected to the second internal channel, wherein the first input/output pads and the second input/output pads are alternately arranged for each channel.

12. The storage device of claim 11,
wherein the first input/output pads and the second input/output pads are arranged in a second row or in a zigzag pattern, and
wherein each of the first nonvolatile memory devices and the second nonvolatile memory devices are configured to be stacked.

13. The storage device of claim 11, wherein, during a read operation or a write operation, the input/output pads are electrically connected to one of the first input/output pads and the input/output pads.

14. The storage device of claim 11,
wherein the first nonvolatile memory devices and the second nonvolatile memory devices include power pads connected to each other or ground pads connected to each other, and
wherein the power pads and the ground pads are connected to the controller through bonding pads.

15. The storage device of claim 11, wherein the first nonvolatile memory devices and the second nonvolatile memory devices are alternately arranged horizontally with a predetermined distance therebetween.

16. A method of manufacturing a nonvolatile memory package, the method comprising:
manufacturing a buffer chip on a first sub-silicon substrate;
manufacturing nonvolatile memory chips stacked on a second sub-silicon substrate; and
connecting the buffer chip to the nonvolatile memory chips using cross-channel shielding,
wherein the buffer chip includes:
input/output pads connected to a bonding channel;
first input/output pads connected to a first bonding channel; and
second input/output pads connected to a second bonding channel, wherein the first input/output pads and the second input/output pads are alternately arranged for each channel.

17. The method of claim 16,
wherein the first input/output pads and the second input/output pads are arranged in a row or arranged in a zigzag pattern,
wherein the nonvolatile memory chips include first nonvolatile memory chips and second nonvolatile memory chips,
wherein the connecting includes:
connecting the first bonding channel to one of the first nonvolatile memory chips; and
connecting the second bonding channel to one of the second nonvolatile memory chips.

18. The method of claim 16,
wherein each of the nonvolatile memory chips includes signal pads, a ground pad, and a power pad, and
wherein one of the ground pad and the power pad is disposed between the signal pads.

19. The method of claim 18, further comprising:
connecting the ground pad and the power pad to corresponding bonding pads.

20. The method of claim 16, further comprising:
disposing the first sub-silicon substrate and the second sub-silicon substrate on a package board.
